(19) United States
(12) Patent Application Publication
(10) Pub. No.: US 2022/0302077 A1
(43) Pub. Date: Sep. 22, 2022

(54) BONDING APPARATUS, BONDING SYSTEM, AND BONDING METHOD

(71) Applicant: Tokyo Electron Limited, Tokyo (JP)

(72) Inventors: Takashi Terada, Koshi-shi, Kumamoto (JP); Takayuki Ishii, Koshi-shi, Kumamoto (JP)

(21) Appl. No.: 17/636,455

(22) PCT Filed: Aug. 12, 2020
(86) PCT No.: PCT/JP2020/030700

§ 371 Date: Feb. 18, 2022

(30) Foreign Application Priority Data
Aug. 23, 2019 (JP) 2019-153201

(51) Int. Cl. H01L 23/00; H01L 21/683; H01L 21/66

(52) U.S. Cl. CPC H01L 24/75; H01L 21/6836; H01L 22/12; H01L 24/83; H01L 2224/83895; H01L 2224/83896; H01L 2224/8313; H01L 2224/75753; H01L 2224/7555

(57) ABSTRACT

A bonding apparatus includes a first holder configured to hold a first substrate divided into multiple chips with a tape and a ring frame therebetween, the first substrate being attached to the tape, and an edge of the tape being attached to the ring frame; a second holder configured to hold a second substrate, which is disposed on an opposite side to the tape with respect to the first substrate therebetween, while maintaining a distance from the first substrate; and a pressing device configured to press the multiple chips one by one with the tape therebetween to press and bond the corresponding chip to the second substrate.

### TECHNICAL FIELD

The various aspects and embodiments described herein pertain generally to a bonding apparatus, a bonding system, and a bonding method.

### BACKGROUND

Patent Document 1 discloses a manufacturing method for semiconductor chips. This manufacturing method includes the following processes (1) to (8) which are performed in this sequence. (1) By radiating laser light to a first main surface of a semiconductor wafer, a modified portion is formed at a division line inside the semiconductor wafer. A semiconductor circuit is previously formed on the first main surface. (2) An adhesive film is attached to the first main surface of the semiconductor wafer. The adhesive film is previously stacked on an adhesive tape, and is positioned between the adhesive tape and the semiconductor wafer. (3) A second main surface of the semiconductor wafer is ground. (4) The grinding is ended at a time point when the thickness of the semiconductor wafer reaches a target thickness. (5) A pick-up tape is attached to the second main surface of the semiconductor wafer, and the semiconductor wafer is fixed to a ring frame with the pick-up tape therebetween. (6) The adhesive film and the adhesive tape are separated, leaving only the adhesive film on the semiconductor wafer. (7) By expanding the pick-up tape and separating the adhesive film and the semiconductor wafer, chips with the adhesive film attached thereto are obtained. (8) The chip with the adhesive film attached thereto is picked up by a first collet. The first collet holds the chip with the adhesive film therebetween (FIG. 2 of Patent Document 1). Thereafter, the first collet is turned upside down, and transfers the chip with the adhesive film attached thereto to a second collet. The second collet holds the chip from above, allowing the adhesive film to face down. The second collet presses the chip onto a top surface of a substrate with the adhesive film therebetween to mount the chip on the substrate.

### PRIOR ART DOCUMENT

Patent Document 1: International Publication No. 2014/080918

### DISCLOSURE OF THE INVENTION

### Problems to be Solved by the Invention

Exemplary embodiments provide a technique enabling to suppress contamination of a bonding surface of a chip.

### Means for Solving the Problems

In an exemplary embodiment, a bonding apparatus includes a first holder configured to hold a first substrate divided into multiple chips with a tape and a ring frame therebetween, the first substrate being attached to the tape, and an edge of the tape being attached to the ring frame; a second holder configured to hold a second substrate, which is disposed on an opposite side to the tape with respect to the first substrate therebetween, while maintaining a distance from the first substrate; and a pressing device configured to press the multiple chips one by one with the tape therebetween to press and bond the corresponding chip to the second substrate.

### Effect of the Invention

According to the exemplary embodiments, it is possible to suppress the contamination of the bonding surface of the chip.

### BRIEF DESCRIPTION OF THE DRAWINGS

FIG. 1 is a plan view illustrating a bonding system according to an exemplary embodiment.

FIG. 2 is a side view illustrating the bonding system of FIG. 1.

FIG. 3 is a perspective view illustrating an example of a first substrate.

FIG. 4 is a perspective view illustrating an example of a second substrate.

FIG. 5 is a flowchart illustrating a bonding method according to the exemplary embodiment.

FIG. 6A is a cross sectional view illustrating a bonding apparatus according to the exemplary embodiment.

FIG. 6B is a cross sectional view illustrating an operation of the bonding apparatus, following that shown in FIG. 6A.

FIG. 6C is a cross sectional view illustrating an operation of the bonding apparatus, following that shown in FIG. 6B.

FIG. 6D is a cross sectional view illustrating an operation of the bonding apparatus, following that shown in FIG. 6C.

FIG. 6E is an enlarged cross sectional view illustrating a part of FIG. 6D.

FIG. 6F is a cross sectional view illustrating an operation of the bonding apparatus, following that shown in FIG. 6D.

FIG. 7 is a flowchart illustrating an example of a process S6 of FIG. 5.

FIG. 8A is a cross sectional view illustrating a bonding apparatus according to a modification example.

FIG. 8B is a cross sectional view illustrating an operation of the bonding apparatus, following that shown in FIG. 8A.

FIG. 9 is a flowchart illustrating a modification example of the process S6 of FIG. 5.

### DETAILED DESCRIPTION

Hereinafter, exemplary embodiments of the present disclosure will be described with reference to the accompanying drawings. In the various drawings, same or corresponding parts will be assigned same or corresponding reference numerals, and redundant description will be omitted. In the present specification, the X-axis direction, the Y-axis direction, and the Z-axis direction are perpendicular to each other. The X-axis direction and the Y-axis direction are horizontal directions, and the Z-axis direction is a vertical direction.

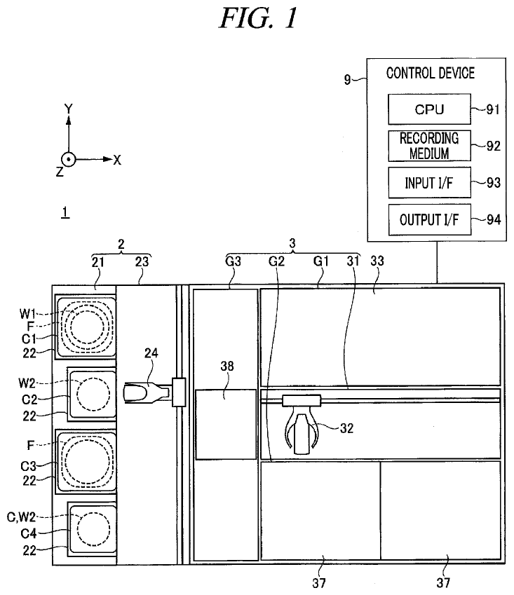

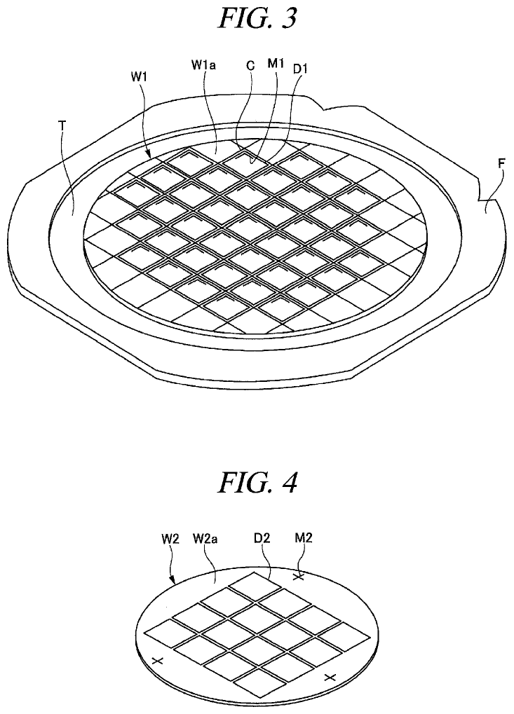

A bonding system 1 shown in FIG. 1 is configured to bond a first substrate W1 and a second substrate W2. The first substrate W1 is divided into a plurality of chips C as shown in FIG. 3, and the chips C are bonded to the second substrate W2 one by one. Only the chips C with good quality can be bonded to the second substrate W2, so that yield can be improved.

Since the first substrate W1 is divided into the plurality of chips C as illustrated in FIG. 3, to be supported by a tape T. An edge of the tape T is attached to a ring frame F, and the first substrate W1 and the tape T are attached in an opening of the ring frame F. The tape T covers a non-bonding surface of the first substrate W1 opposite to a bonding surface W1a thereof.

The first substrate W1 includes a first device D1 for each chip C. The first device D1 is formed on the bonding surface W1a of the first substrate W1. The first device D1 includes a semiconductor device, a circuit, a terminal, and the like. In addition, the first device D1 includes a first silicon oxide layer which serves as a bonding layer. The first device D1 may further include a first conductive layer inside the first silicon oxide layer. The first conductive layer is configured to electrically connect the first device D1 to a second device D2 to be described later.

The second substrate W2 includes the previously formed second device D2, as shown in FIG. 4. The second device D2 is plural in number, and these second devices D2 are formed on a bonding surface W2a of the second substrate W2 while being distanced apart from each other. The second device D2 includes a semiconductor element, a circuit, a terminal, and the like. In addition, the second device D2 includes a second silicon oxide layer which serves as a bonding layer. The second device D2 may further include a second conductive layer inside the second silicon oxide layer. The second conductive layer is configured to electrically connect the second device D2 and the first device D1.

The first silicon oxide layer and the second silicon oxide layer are bonded to each other by a dehydration condensation reaction or the like between hydrophilic groups as will be described later. Further, the first conductive layer and the second conductive layer are formed of the same material and bonded to each other by thermal diffusion or the like. Here, the way how to bond them is not particularly limited. For example, solder or DAF (Die Attachment Film) may be used as a bonding layer.

When viewed from a direction perpendicular to the bonding surfaces W1a and W2a, the size of the chip C and the size of the second device D2 may be same or different. When the size of the chip C and the size of the second device D2 are different, since the pitch of the chip C changes before and after the bonding, it is of great significance to bond the chips C to the second substrate W2 one by one. Further, when the size of the chip C is smaller than the size of the second device D2, since the chip C does not stick out from the second device D2, it is easy to press the chip C.

When the size of the chip C and the size of the second device D2 are different, the number of the chips C and the number of the second devices D2 are also different. Thus, the first substrate W1 or the second substrate W2 may be replaced while repeating the work of pressing the chip C onto the second substrate W2. When the number of the remaining good-quality chips C becomes zero, the replacement of the first substrate W1 is performed. Further, when the number of the second devices D2 yet to be bonded becomes zero, the replacement of the second substrate W2 is performed.

As depicted in FIG. 1, the bonding system 1 includes a carry-in/out station 2, a processing station 3, and a control device 9. The carry-in/out station 2 and the processing station 3 are arranged in this order from the negative X-axis side toward the positive X-axis side.

The carry-in/out station 2 is equipped with a placing table 21, and the placing table 21 is equipped with a plurality of placing plates 22. A plurality of cassettes C1, C2, C3, and C4 are respectively disposed on the plurality of placing plates 22. By way of example, the cassette C1 accommodates therein the first substrate W1 with the ring frame F attached thereto; the cassette C2, the second substrate W2; the cassette C3, the ring frame F; and the cassette C4, the second substrate W2 with the chip C attached thereto. Here, the number of the placing plates 22 is not particularly limited. Likewise, the number of the cassettes C1 to C4 is not specifically limited, either.

The carry-in/out station 2 is provided with a first transfer area 23, and the first transfer area 23 is adjacent to the placing table 21 on the positive X-axis side of the placing table 21. A first transfer device 24 is provided in the first transfer area 23. The first transfer device 24 has a transfer arm, and this transfer arm is configured to be moved in horizontal directions (the X-axis direction and the Y-axis direction) and a vertical direction, and pivotable around a vertical axis. The transfer arm transfers the first substrate W1 with the ring frame F attached thereto, the second substrate W2, the ring frame F, and the second substrate W2 with the chip C attached thereto between the plurality of cassettes C1 to C4 and a third processing block G3 to be described later. The number of the transfer arm may be one or more.

The processing station 3 is equipped with, by way of example, a first processing block G1, a second processing block G2, a third processing block G3, and a second transfer area 31. The second transfer area 31 is adjacent to the first to third processing blocks G1 to G3, and is disposed on the negative Y-axis side of the first processing block G1, the positive Y-axis side of the second processing block G2 and the positive X-axis side of the third processing block G3.

A second transfer device 32 is disposed in the second transfer area 31. The second transfer device 32 has a transfer arm, and this transfer arm is configured to be moved in horizontal directions (the X-axis direction and the Y-axis direction) and a vertical direction, and pivotable around a vertical axis. The transfer arm transfers the first substrate W1 with the ring frame F attached thereto, the second substrate W2, the ring frame F, and the second substrate W2 with the chip C attached thereto between the first processing block G1, the second processing block G2, and the third processing block G3. The number of the transfer arm may be one or plural.

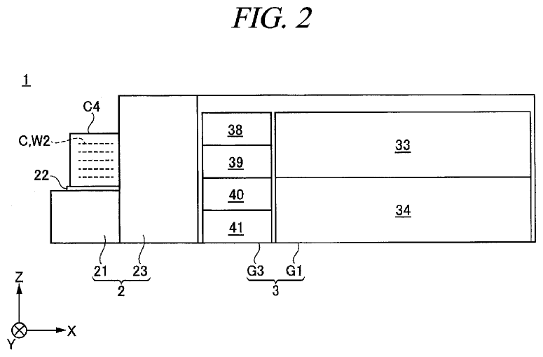

As depicted in FIG. 2, a surface modifying apparatus 33 and a surface hydrophilizing apparatus 34 are disposed in the first processing block G1. In FIG. 2, in order to illustrate the apparatuses of the first processing block G1, illustration of apparatuses of the second processing block G2 and the second transfer device 32 shown in FIG. 1 is omitted. The kinds and the layout of the apparatuses of the first processing block G2 are not limited to those shown in FIG. 2. For example, the surface modifying apparatus 33 and the surface hydrophilizing apparatus 34 may be stacked in the vertically opposite way.

The surface modifying apparatus 33 is configured to modify the bonding surface W1a of the first substrate W1. For example, the surface modifying apparatus 33 cuts a SiO₂ bond of the bonding surface W1a to form a dangling bond of Si, and enables hydrophilization of the bonding surface W1a. In the surface modifying apparatus 33, an oxygen gas as a processing gas is excited into plasma under, for example, a decompressed atmosphere to be ionized. As oxygen ions are radiated to the bonding surface W1a, the bonding surface W1a is modified. The processing gas is not limited to the oxygen gas, and may be, for example, a nitrogen gas, or the like. The surface modifying apparatus 33 modifies the bonding surface W2a of the second substrate W2 as well as the bonding surface W1a of the first substrate W1. The surface modifying apparatus 33 may be plural in number, and the one for the first substrate W1 and the one for the second substrate W2 may be provided separately.

The surface hydrophilizing apparatus 34 is configured to hydrophilize the bonding surface W1a of the first substrate W1. For example, the surface hydrophilizing apparatus 34 holds the first substrate W1 with a spin chuck, and supplies pure water such as DIW (deionized water) onto the bonding surface W1a of the first substrate W1 being rotated along with the spin chuck. As an OH group combines with the dangling bond of Si of the bonding surface W1a, the bonding surface W1a is hydrophilized. The surface hydrophilizing apparatus 34 hydrophilizes the bonding surface W2a of the second substrate W2 as well as the bonding surface W1a of the first substrate W1. The surface hydrophilizing apparatus 34 may be plural in number, and the one for the first substrate W1 and the one for the second substrate W2 may be provided separately.

The bonding apparatus 37 is disposed in the second processing block G2, as shown in FIG. 1. The kinds and the layout of the apparatuses disposed in the second processing block G2 are not limited to the example shown in FIG. 1.

The bonding apparatus 37 arranges the bonding surface W1a of the first substrate W1 and the bonding surface W2a of the second substrate W2 to face each other, and bonds the chips C of the first substrate W1 to the second substrate W2 one by one. Since the bonding surface W1a of the first substrate W1 and the bonding surface W2a of the second substrate W2 are modified, a van der Waals force (intermolecular force) is generated, so that the bonding surfaces W1a and W2a are bonded to each other. In addition, since the bonding surface W1a of the first substrate W1 and the bonding surface W2a of the second substrate W2 are hydrophilized, hydrophilic groups such as OH groups undergo a dehydration condensation reaction, so that the bonding surfaces W1a and W2a are strongly bonded to each other. Details of the bonding apparatus 37 will be described later.

In the third processing block G3, a first transition device 38, a second transition device 39, a third transition device 40, and a fourth transition device 41 are disposed, as depicted in FIG. 2. The first transition device 38 temporarily stores the first substrate W1 with the ring frame F attached thereto. The second transition device 39 temporarily stores the second substrate W2. The third transition device 40 temporarily stores the ring frame F. The fourth transition device 41 temporarily stores the second substrate W2 with the chip C attached thereto. Here, the kinds and the layout of the devices of the third processing block G3 are not particularly limited.

The control device 9 is, for example, a computer, and includes a CPU (Central Processing Unit) 91 and a recording medium 92 such as a memory, as shown in FIG. 1. The recording medium 92 stores thereon a program for controlling various processings performed in the bonding system 1. The control device 9 causes the CPU 91 to execute the program stored in the recording medium 92 to thereby control the operation of the bonding system 1. Further, the control device 9 includes an input interface 93 and an output interface 94. The control device 9 receives a signal from the outside through the input interface 93, and transmits a signal to the outside through the output interface 94.

The program is stored in, for example, a computer-readable recording medium, and installed from this recording medium to the recording medium 92 of the control device 9. The computer-readable recording medium may be, by way of non-limiting example, a hard disk (HD), a flexible disk (FD), a compact disk (CD), a magnet optical disk (MO), a memory card, or the like. In addition, the program may be downloaded from a server via the Internet and installed in the recording medium 92 of the control device 9.

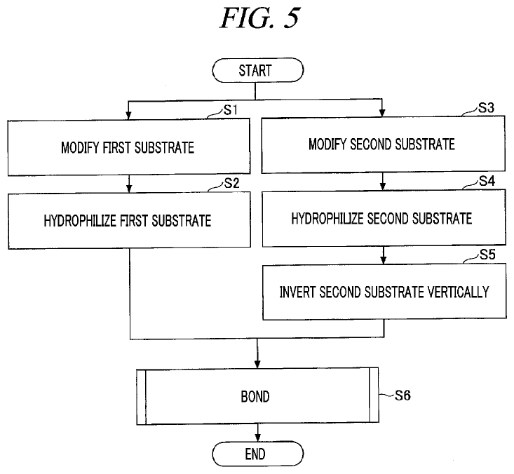

Now, referring to FIG. 5, an operation of the bonding system 1, that is, a bonding method will be explained. Processes shown in FIG. 5 are performed under the control of the control device 9.

First, the cassette C1 accommodating therein a plurality of first substrates W1 each of which has the ring frame F attached thereto, the cassette C2 accommodating therein a plurality of second substrates W2, and empty cassettes C3 and C4 are arranged on the preset placing plates 22 of the carry-in/out station 2. Each of the first substrates W1 is previously divided into a plurality of chips C, and is held by the tape T. The edge of the tape T is attached to the ring frame F, and the first substrate W1 and the tape T are attached in the opening of the ring frame F. The first substrate W1 is accommodated in the cassette C1 with its bonding surface W1a facing upwards. Likewise, the second substrate W2 is accommodated in the cassette C2 with its bonding surface W2a facing upwards.

Next, the first transfer device 24 takes out the first substrate W1 from the cassette C1 and transfers it to the first transition device 38. The first transfer device 24 holds the first substrate W1 with the ring frame F therebetween. Next, the second transfer device 32 receives the first substrate W1 from the first transition device 38, and transfers it to the surface modifying apparatus 33. The second transfer device 32 holds the first substrate W1 with the ring frame F therebetween.

Next, the surface modifying apparatus 33 modifies the bonding surface W1a of the first substrate W1 (S1 of FIG. 5). Thereafter, the second transfer device 32 transfers the first substrate W1 from the surface modifying apparatus 33 to the surface hydrophilizing apparatus 34.

Next, the surface hydrophilizing apparatus 34 hydrophilizes the bonding surface W1a of the first substrate W1 (S2 of FIG. 5). Thereafter, the second transfer device 32 transfers the first substrate W1 from the surface hydrophilizing apparatus 34 to the bonding apparatus 37.

Subsequently, before the bonding of the chip C of the first substrate W1 and the second substrate W2 (S6 of FIG. 5) is performed, modification (S3 of FIG. 5), hydrophilization (S4 of FIG. 5), and vertical inversion (S5 of FIG. 5) of the second substrate W2 are performed.

First, the first transfer device 24 takes out the second substrate W2 from the cassette C2 and transfers it to the second transition device 39. Next, the second transfer device 32 receives the second substrate W2 from the second transition device 39 and transfers it to the surface modifying apparatus 33.

Subsequently, the surface modifying apparatus 33 modifies the bonding surface W2a of the second substrate W2 (S3 of FIG. 5). Thereafter, the second transfer device 32 transfers the second substrate W2 from the surface modifying apparatus 33 to the surface hydrophilizing apparatus 34.

Then, the surface hydrophilizing apparatus 34 hydrophilizes the bonding surface W2a of the second substrate W2 (S4 of FIG. 5). Thereafter, the second transfer device 32 transfers the second substrate W2 from the surface hydrophilizing apparatus 34 to the bonding device 37.

Subsequently, the bonding apparatus 37 inverts the second substrate W2 upside down, making the bonding surface W2a of the second substrate W2 face downwards (S5 of FIG. 5). In addition, although an inverting device configured to vertically invert the second substrate W2 is provided inside the bonding apparatus 37 in the present exemplary embodiment, it may be provided outside the bonding apparatus 37.

Subsequently, the bonding apparatus 37 arranges the bonding surface W1a of the first substrate W1 and the bonding surface W2a of the second substrate W2 to face each other, and bonds the first substrate W1 and the second substrate W2 together (S6 of FIG. 5). The chips C of the first substrate W1 are bonded to the second substrates W2 one by one, so that the second substrate W2 with the chips C attached thereto is obtained. Details of the bonding of the chips C and the second substrate W2 will be explained later.

Thereafter, the second transfer device 32 transfers the second substrate W2 with the chips C attached thereto to the fourth transition device 41 from the bonding apparatus 37. Then, the first transfer device 24 receives the second substrate W2 with the chips C attached thereto from the fourth transition device 41, and accommodates it in the cassette C4. Thereafter, the second substrate W2 with the chips C attached thereto is carried out to the outside of the bonding system 1 along with the cassette C4, and is divided into a plurality of chips. Each of the divided chips includes the first device D1 and the second device D2.

Moreover, the second transfer device 32 transfers the ring frame F from the bonding apparatus 37 to the third transition device 40. No chip C with good quality may remain in the opening of the ring frame F, but a defective chip C may be left therein. Subsequently, the first transfer device 24 receives the ring frame F from the third transition device 40, and accommodates the received ring frame F in the cassette C3.

In the present exemplary embodiment, although both the bonding surface W1a of the first substrate W1 and the bonding surface W2a of the second substrate W2 are modified and hydrophilized before the bonding of the first substrate W1 and the second substrate W2, the present disclosure is not limited thereto. Only one of the bonding surface W1a of the first substrate W1 and the bonding surface W2a of the second substrate W2 may be modified and hydrophilized.

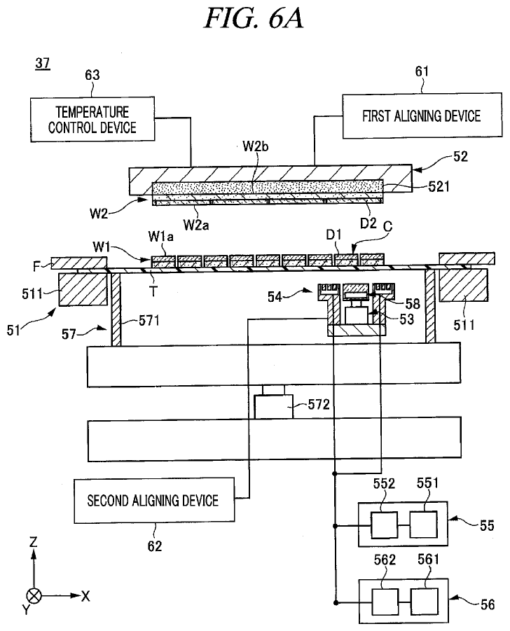

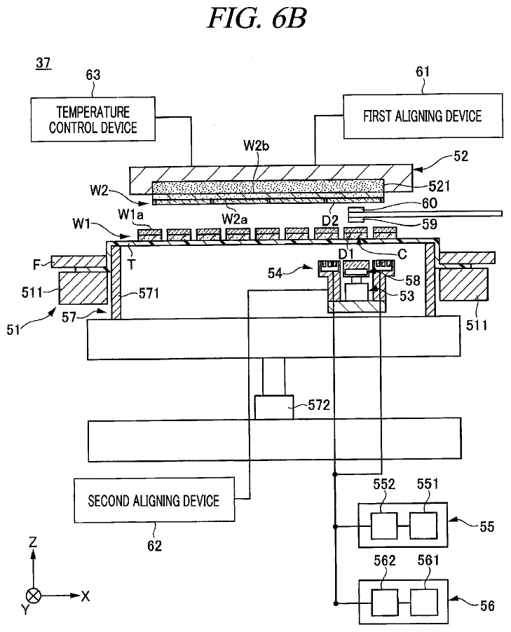

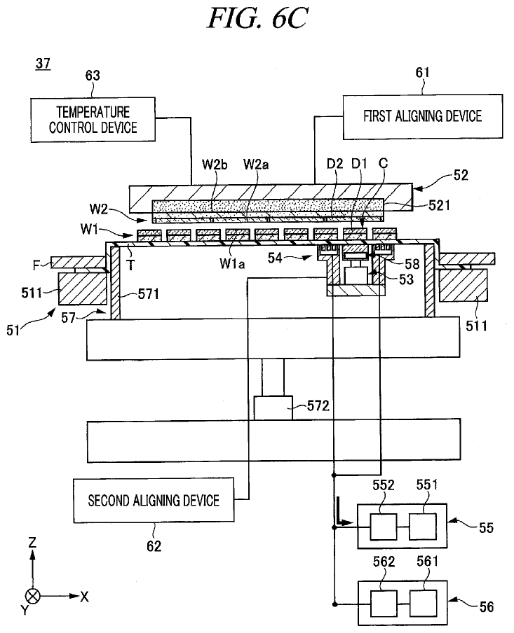

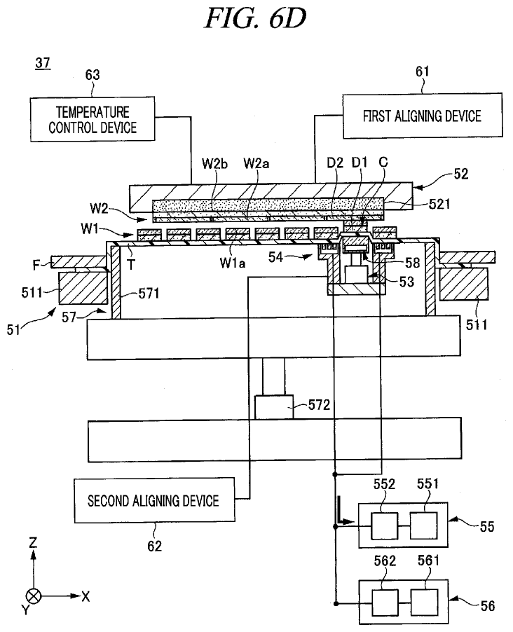

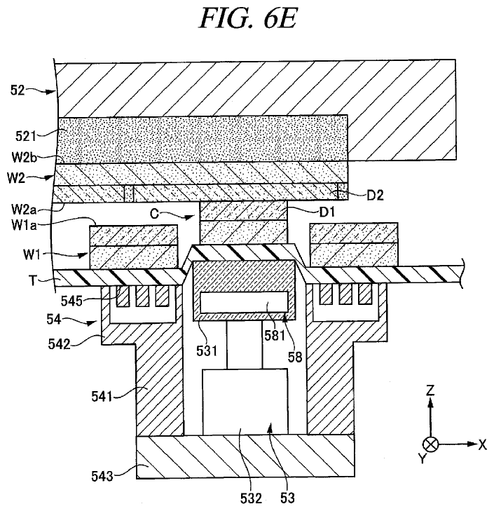

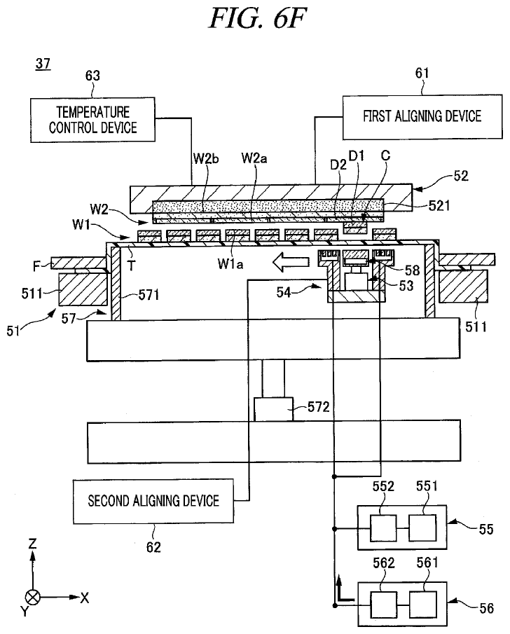

Now, referring to FIG. 6A, etc., details of the bonding apparatus 37 will be described. The bonding apparatus 37 includes a first holder 51, a second holder 52, and a pressing device 53 at least.

As shown in FIG. 6A, the first holder 51 holds the ring frame F, and holds the first substrate W1 with the ring frame F and the tape T therebetween. For example, the first holder 51 holds the first substrate W1 horizontally from below, allowing the bonding surface W1a of the first substrate W1 to face upwards.

The first holder 51 includes an attraction pad 511 configured to attract the ring frame F. Although the attraction pad 511 attracts the ring frame F with the tape T therebetween as shown in FIG. 6A, it may be configured to attract the ring frame F without the tape T therebetween.

The attraction pad 511 is disposed at a diametrically outer side than the opening of the ring frame F so that the tape T may be easily expanded radially. The attraction pad 511 may be formed in a ring shape, or may be formed in an arc shape. The arc-shaped attraction pad 511 may be plural in number, and these arc-shaped attraction pads 511 may be arranged while being distanced apart in a circumferential direction.

The attraction pad 511 is connected to a vacuum pump via a pipeline. If the control device 9 operates the vacuum pump, the attraction pad 511 vacuum-attracts the ring frame F. Moreover, the attraction pad 511 may attract the ring frame F electrostatically, or may attract the ring frame F with a magnet.

As illustrated in FIG. 6A, the second holder 52 holds the second substrate W2, which is disposed on the opposite side to the tape T with respect to the first substrate W1 therebetween, while maintaining a certain distance from the first substrate W1. For example, the second holder 52 holds the second substrate W2 horizontally from above, allowing the bonding surface W2a of the second substrate W2 to face down.

The second substrate W2 includes the bonding surface W2a and a non-bonding surface W2b opposite to the bonding surface W2a. The second holder 52 attracts the entire non-bonding surface W2b of the second substrate W2 to maintain the second substrate W2 flat. When the chip C is pressed against the second substrate W2, deformation of the second substrate W2 can be restricted.

The second holder 52 includes a porous body 521 configured to attract the non-bonding surface W2b of the second substrate W2 as a whole. The porous body 521 is connected to a vacuum pump via a pipeline. If the control device 9 operates the vacuum pump, the porous body 521 vacuum-attracts the second substrate W2. Although the second holder 52 is a vacuum chuck in the present exemplary embodiment, it may be an electrostatic chuck or a mechanical chuck.

Further, the positions of the first holder 51 and the second holder 52 may be reversed, so the first holder 51 may be disposed at the upper side, and the second holder 52 may be disposed at the lower side. In this case, the first holder 51 horizontally holds the first substrate W1 from above, allowing the bonding surface W1a of the first substrate W1 to face down, and the second holder 52 horizontally holds the second substrate W2 from below, allowing the bonding surface W2a of the second substrate W2 to face upwards.

As illustrated in FIG. 6D and FIG. 6E, the pressing device 53 presses the chips C one by one with the tape T therebetween. The pressing device 53 presses each chip C onto the second substrate W2 to bond the chip C to the second substrate W2. Unlike in the prior art, a bonding surface of the chip C is not held by a collet. Thus, contamination on the bonding surface of the chip C can be suppressed. Further, since the collet and its guide rail are not provided, particle generation due to friction between the collet and the guide rail can be suppressed, and the contamination on the bonding surface of the chip C can be further suppressed. This effect is particularly advantageous when a silicon oxide layer is used as the bonding layer in consideration of the fact that the silicon oxide layer requires high degree of cleanliness as compared to the solder and the DAF (Die Attachment Film).

As depicted in FIG. 6E, the pressing device 53 includes, for example, a pressing head 531 and an actuator 532. Since the pressing head 531 presses the chip C with the tape T therebetween, it is disposed on the opposite side to the chip C with the tape T therebetween. Although the size of the pressing head 531 may be larger or smaller than the size of the chip C as long as it can press the chips C one by one, the size of the pressing head 531 may be the same as the size of the chip C in the present exemplary embodiment. The actuator 532 presses the pressing head 531 upwards with a constant force by, for example, the air supplied from an electro-pneumatic regulator.

The bonding apparatus 37 may further include an attracting device 54, as shown in FIG. 6E. The attracting device 54 attracts the neighboring chip C next to the chip C pressed by the pressing device 53 with the tape T therebetween, thus suppressing this neighboring chip C from coming into contact with the second substrate W2. When the tape T is pressed by the pressing device 53, a deformation range of the tape T can be delimited, so that the chips C can be securely pressed onto the second substrate W2 one by one.

The attracting device 54 includes, for example, a cylindrical member 541 surrounding the pressing device 53, a flange member 542 formed at one end of the cylindrical member 541, and a cover 543 formed at the other end of the cylindrical member 541. The pressing device 53 is provided at the cover 543, and presses the tape T in an opening of the flange member 542. The flange member 542 attracts the tape T and delimits the deformation range of the tape T.

The attracting device 54 is connected to a gas suction device 55 via a pipeline, as shown in FIG. 6D. The gas suction device 55 sucks a gas from an attraction surface 545 of the attracting device 54 shown in FIG. 6E, thus allowing the tape T to be attracted to the attraction surface 545. The attraction surface 535 is provided with a plurality of holes, and the gas suction device 55 sucks the gas from the holes of the attraction surface 545 to generate an attracting force in the attraction surface 545.

The gas suction device 55 includes, as illustrated in FIG. 6D, an exhaust source 551 such as a vacuum pump, and a pressure controller 552 provided at a portion of a pipeline. If the control device 9 operates the exhaust source 551, an air pressure in the holes of the attraction surface 545 becomes lower than the atmospheric pressure. The air pressure in the holes of the attraction surface 545 is controlled by the pressure controller 552.

Further, the attracting device 54 is connected to a gas supply 56 via a pipeline, as shown in FIG. 6F. The gas supply 56 supplies a gas to the attracting device 54, and discharges the gas from the attraction surface 545 of the attracting device 54 toward the tape T. Although holes for the discharge and holes for the attraction may be set to be different, they are the same holes in the present exemplary embodiment.

When releasing the attraction between the attraction surface 545 and the tape T, the gas supply 56 discharges the gas from the attraction surface 545 in order to separate the attraction surface 545 and the tape T reliably. Further, when moving the attraction surface 545 and the tape T relatively, the gas supply 56 discharges the gas from the attraction surface 545 to suppress a contact between the attraction surface 545 and the tape T.

The gas supply 56 includes, for example, a supply source 561 and a flow rate controller 562 provided at a portion of the pipeline. If the control device 9 operates the supply source 561, the gas having a pressure higher than the atmospheric pressure is supplied to the attracting device 54. A flow rate of the gas is controlled by the flow rate controller 562.

The bonding apparatus 37 may further include an expanding device 57, as depicted in FIG. 6B. The expanding device 57 stretches the tape T radially before the chip C is pressed onto the second substrate W2 by the pressing device 53, to thereby enlarge a gap between the adjacent chips C. Accordingly, when the chip C is pressed onto the second substrate W2 by the pressing device 53, it is possible to suppress the chips C from being rubbed against each other.

The expanding device 57 includes, for example, a cylindrical drum 571 disposed inside the ring frame F, and a driving unit 572 configured to move the drum 571 with respect to the ring frame F. An outer diameter of the drum 571 is smaller than an inner diameter of the ring frame F, and an inner diameter of the drum 571 is larger than a diameter of the first substrate W1. The driving unit 572 moves the drum 571 upwards, allowing the tape T to be radially stretched.

Further, in the present exemplary embodiment, although the first substrate W1 is already divided into the plurality of chips C as shown in FIG. 3, it does not need to be in this divided state, and may be divided when the tape T is expanded. In case that the first substrate W1 is divided when the tape T is expanded, a modified portion is formed on a dividing line by using a laser beam, the same as in the prior art. When the first substrate W1 is single crystal silicon, the modified portion is amorphous silicon.

The bonding apparatus 37 may further include an adhesive force reducing device 58, as shown in FIG. 6E. The adhesive force reducing device 58 is configured to reduce an adhesive force of the tape T at an interface between the tape T and the chip C pressed onto the second substrate W2 by the pressing device 53. The tape T and the second substrate W2 with the chip C attached thereto can be detached, and the tape T can be removed from the second substrate W2 with the chip C attached thereto.

The adhesive force reducing device 58 includes, for example, a light source 581 configured to radiate light to the tape T. The light source 581 is provided inside the transparent pressing head 531, for example. The tape T includes a sheet and an adhesive coated on the surface of the sheet, and is bonded to the chip C by the adhesive force of the adhesive. If the light is radiated, the adhesive is hardened, having a reduced adhesive force. The light of the light source 581 is, for example, ultraviolet rays.

Moreover, the tape T may contain a microcapsule which expands or foams by the radiation of the light, a foaming agent which foams by the radiation of the light, or the like. In addition, the tape T may be of a type which is sublimated by the radiation of the light.

Although the light may have a radiation range larger or smaller than the size of the chip C as long as the chips C can be detached from the tape T one by one, the radiation range of the light may be about the same as the size of the chip C. The light can be radiated to non-bonding surfaces of the chips C all at once. In addition, when the radiation range of the light is smaller than the size of the chip C, the adhesive force reducing device 58 may further include a scanning device configured to scan the light on the surface of the tape T.

In addition, the adhesive force reducing device 58 may have a heater instead of the light source 581. The heater heats the tape T and reduces the adhesive force of the tape T. In this case, the pressing head 531 need not be transparent.

The bonding apparatus 37 may be further equipped with a first imaging device 59, as shown in FIG. 6B. The first imaging device 59 is configured to image the bonding surface W1a of the first substrate W1 and first marks M1 of the first substrate W1 shown in FIG. 3. The control device 9 detects a position of each first mark M1 by image-processing the image of the first mark M1 obtained by the first imaging device 59. As an example of the first mark M1, a part of the first device D1 of the chip C may be used. Accordingly, the position of each chip C can be detected.

The first imaging device 59 is inserted into a gap between the first substrate W1 and the second substrate W2 to image the first mark M1 of the first substrate W1. The first imaging device 59 is then retreated from the gap between the first substrate W1 and the second substrate W2 before the chip C is pressed by the pressing device 53.

The bonding apparatus 37 may be further equipped with a second imaging device 60, as shown in FIG. 6B. The second imaging device 60 images the bonding surface W2a of the second substrate W2 and second marks M2 of the second substrate W2 shown in FIG. 4. The control device 9 detects a position of each second mark M2 by image-processing the image of the second mark M2 obtained by the second imaging device 60. As an example of the second mark M2, an alignment mark formed at an outside of the second device D2 may be used. Alternatively, a part of the second device D2 may be used as the second mark M2, the same as the first mark M1.

The second imaging device 60 is inserted into the gap between the first substrate W1 and the second substrate W2 to image the second mark M2 of the second substrate W2. The second imaging device 60 is retreated from the gap between the first substrate W1 and the second substrate W2 before the chip C is pressed by the pressing device 53.

In the present exemplary embodiment, the second imaging device 60 is integrated as one body with the first imaging device 59, and moved concurrently with the first imaging device 59. Here, however, the first imaging device 59 and the second imaging device 60 may be moved independently.

The bonding apparatus 37 may further include a first aligning device 61, as shown in FIG. 6C. The first aligning device 61 is configured to align the first substrate W1 and the second substrate W2 with reference to the positions of the first mark M1 and the second mark M2. Accordingly, the chip C of the first substrate W1 can be pressed onto a desired position on the second substrate W2.

The first aligning device 61 moves, for example, the second holder 52 in the X-axis direction and the Y-axis direction, and rotates it around a vertical axis. Accordingly, horizontal alignment between the first substrate W1 and the second substrate W2 is carried out. For this horizontal alignment, the first mark M1 and the second mark M2 are used.

The first aligning device 61 may further move the second holder 52 in the Z-axis direction. Accordingly, vertical alignment between the first substrate W1 and the second substrate W2 is performed. A distance between the first substrate W1 and the second substrate W2 is measured with an encoder or the like, and this distance is set to be of a value at which the chip C can be pressed onto the second substrate W2 by the deformation of the tape T.

In addition, the first aligning device 61 only needs to move the first holder 51 and the second holder 52 relatively. It may move the first holder 51 instead of the second holder 52, or in addition to the second holder 52.

The bonding apparatus 37 may be further equipped with a second aligning device 62, as shown in FIG. 6C. The second aligning device 62 is configured to align the chip C of the first substrate W1 and the pressing device 53 by referring to the position of the first mark M1. Accordingly, the required chip C can be pressed.

The second aligning device 62 moves, for example, the pressing device 53 in the X-axis direction and the Y-axis direction, and rotates it around a vertical axis. Accordingly, horizontal alignment between the pressing device 53 and the chip C is performed. For this horizontal alignment, the first mark M1 is used.

The second aligning device 62 may further move the pressing device 53 in the Z-axis direction. Accordingly, vertical alignment between the pressing device 53 and the tape T is carried out. When the pressing device 53 and the chip C are horizontally aligned, a gap may be formed between the pressing device 53 and the tape T to suppress friction between the pressing device 53 and the tape T. A distance between the pressing device 53 and the tape T is measured with an encoder or the like.

The pressing device 53 is integrated as one body with the attracting device 54. For this reason, when the horizontal alignment between the pressing device 53 and the chip C is performed, horizontal alignment between the attracting device 54 and the chip C is also carried out simultaneously. Moreover, when the vertical alignment between the pressing device 53 and the tape T is performed, vertical alignment between the attracting device 54 and the tape T is also carried out simultaneously.

In addition, the second aligning device 62 only needs to move the first holder 51 and the pressing device 53 relatively. It may move the first holder 51 instead of the pressing device 53, or in addition to the pressing device 53.

The bonding apparatus 37 may further include a temperature control device 63, as shown in FIG. 6C. The temperature control device 63 serves to maintain the temperature of the second substrate W2 constant. After the alignment between the first substrate W1 and the second substrate W2, expansion/contraction of the second substrate W2 can be suppressed, so that a position deviation can be suppressed. The temperature control device 63 is configured to supply a temperature control medium into, for example, the second holder 52 to keep the temperature of the second substrate W2 constant. The temperature of the second substrate W2 is maintained at, for example, the room temperature.

In addition, the temperature control device 63 is not limited to a supply device configured to supply the temperature control medium. The temperature control device 63 may be a heat generating element configured to generate heat by an electric power supplied thereto, a Peltier element, or the like. In this case, the temperature control device 63 may be provided in the second holder 52. Furthermore, the temperature control device 63 may be configured to keep the temperature of the first substrate W1 constant. The temperature control device 63 for the first substrate W1 and the temperature control device 63 for the second substrate W2 may be separately provided.

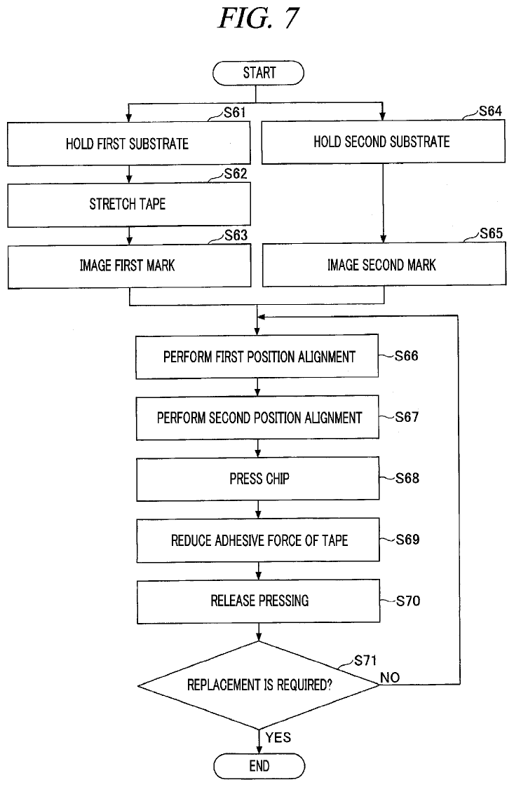

Now, referring to FIG. 7, an operation of the bonding apparatus 37, that is, a bonding method will be discussed. Processes shown in FIG. 7 is performed under the control by the control device 9.

First, as shown in FIG. 6A, the first holder 51 holds the ring frame F and holds the first substrate W1 with the ring frame F and the tape T therebetween (S61 of FIG. 7). The first substrate W1 is held horizontally with its bonding surface W1a facing upwards.

Then, the expanding device 57 stretches the tape T radially to enlarge the gap between the adjacent chips C, as shown in FIG. 6B (S62 of FIG. 7). Specifically, as the cylindrical drum 571 is raised, the tape T is stretched radially, so that the gap between the adjacent chips C is enlarged.

Subsequently, the first imaging device 59 images the bonding surface W1a of the first substrate W1 and the first mark M1 of the first substrate W1, as illustrated in FIG. 6B (S63 of FIG. 7). The control device 9 detects the position of the first mark M1 by image-processing the image of the first mark M1 obtained by the first imaging device 59.

Next, before alignment between the chip C of the first substrate W1 and the second substrate W2 (S66 of FIG. 7) is performed, holding of the second substrate W2 (S64 of FIG. 7) and imaging of the second mark M2 (S65 of FIG. 7) are performed, as will be described later.

First, the second holder 52 holds the second substrate W2, which is disposed on the opposite side to the tape T with respect to the first substrate W1 therebetween, while maintaining a certain distance from the first substrate W1, as shown in FIG. 6A (S64 of FIG. 7). For example, the second substrate W2 is horizontally held from above with the bonding surface W2a thereof facing downwards.

Subsequently, the second imaging device 60 images the bonding surface W2a of the second substrate W2 and the second mark M2 of the second substrate W2, as shown in FIG. 6B (S65 of FIG. 7). The control device 9 detects the position of the second mark M2 by image-processing the image of the second mark M2 obtained by the second imaging device 60.

Thereafter, the first aligning device 61 performs horizontal alignment of the first substrate W1 and the second substrate W2 with reference to the positions of the first and second marks M1 and M2 (S66 of FIG. 7), as shown in FIG. 6C. In addition to the horizontal alignment, vertical alignment is also performed, so that the distance between the first substrate W1 and the second substrate W2 is set to be of a value at which the chip C can be pressed onto the second substrate W2.

Thereafter, the second aligning device 62 performs horizontal alignment between the chip C of the first substrate W1 and the pressing device 53 with reference to the position of the first mark M1, as shown in FIG. 6C (S67 of FIG. 7). In addition to the horizontal alignment, vertical alignment is also performed. The pressing device 53 is brought into contact with the tape T, and is made to face the chip C with the tape T therebetween. Further, the attracting device 54 is brought into contact with the tape T, and is made to face the chip C next to the corresponding chip C pressed by the pressing device 53.

Further, the order of the alignment between the first substrate W1 and the second substrate W2 (S66 of FIG. 7) and the alignment between the chip C of the first substrate W1 and the pressing device 53 (S67 in FIG. 7) may be reversed. Furthermore, the processes S66 and S67 may be performed at the same time.

Next, the pressing device 53 presses the chip C with the tape T therebetween, and presses the corresponding chip C onto the second substrate W2 to bond the chip C to the second substrate W2, as illustrated in FIG. 6D (S68 of FIG. 7). The pressing head 531 is raised to press the chip C onto the second substrate W2. At this time, the attracting device 54 attracts the neighboring chip C next to the corresponding chip C pressed by the pressing device 53 with the tape T therebetween, so that the neighboring chip C my not come into contact with the second substrate W2.

Subsequently, the adhesive force reducing device 58 reduces the adhesive force of the tape T at the interface between the tape T and the chip C pressed onto the second substrate W2 by the pressing device 53, as illustrated in FIG. 6D (S69 of FIG. 7). For example, the light source 581 radiates the light to the tape T to reduce the adhesive force of the tape T.

Thereafter, the pressing device 53 releases the pressing of the chip C onto the second substrate W2, as shown in FIG. 6F (S70 of FIG. 7). Specifically, as the pressing head 531 is lowered, the tape T and the chip C pressed onto the second substrate W2 are detached. Moreover, the attracting device 54 releases the attraction of the tape T.

Next, the control device 9 determines whether the replacement of the first substrate W1 or the second substrate W2 is necessary (S71 of FIG. 7). When a good-quality chip C remains, the replacement of the first substrate W1 is not necessary. When there is left no good-quality chip C, however, the replacement of the first substrate W1 is required. In addition, when the second device D2 yet to be bonded remains, replacement of the second substrate W2 is unnecessary, whereas when there remains no second device D2 yet to be bonded, the replacement of the second substrate W2 is required.

When the replacement of the first substrate W1 or the second substrate W2 is necessary (S71 of FIG. 7, YES), the control device 9 ends the current processing. When the replacement of the first substrate W1 is performed, the control device 9 performs the processes S61 to S63 of FIG. 7, and then performs the processes after S66 of FIG. 7. Meanwhile, when the replacement of the second substrate W2 is performed, the control device 9 performs the processes S64 and S65 of FIG. 7, and then performs the processes after S66 of FIG. 7.

On the other hand, when neither the first substrate W1 nor the second substrate W2 needs to be replaced (S71 of FIG. 7, NO), the control device 9 performs the processes after S66 of FIG. 7. Accordingly, the second substrate W2 with the chips C attached thereto is obtained.

In addition, before the processes after S66 of FIG. 7 are performed again, the imaging of the first mark M1 (S63 of FIG. 7) may be performed again. This is because there is a likelihood that the tape T is stretched and the position of the chip C may be changed when the previous chip C is pressed (S68 of FIG. 7).

It is desirable that the processes S66 and S67 of FIG. 7 are performed by using the first mark M1 of the chip C to be pressed in the process S68 immediately after the processes S66 and 67. The chip C can be securely bonded to a required position on the second device D2. Here, however, it is also possible to perform the processes S66 and S67 of FIG. 7 by using the first mark M1 of the chip C different from the chip C to be pressed in the process S68 immediately after the processes S66 and S67.

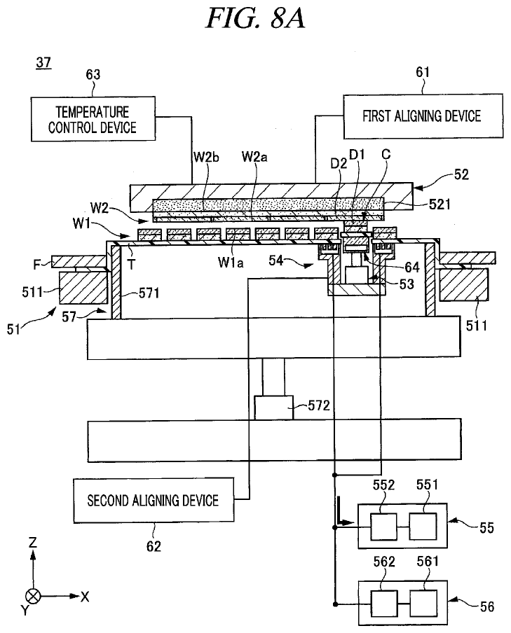

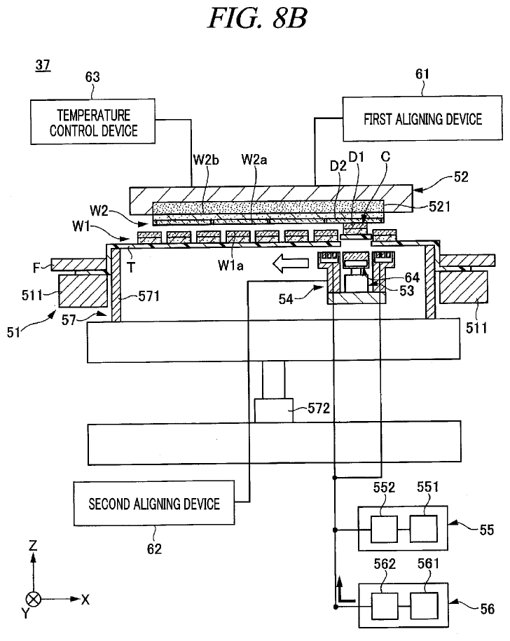

Now, referring to FIG. 8A, etc., the bonding apparatus 37 according to a modification example will be described. Hereinafter, the description will mainly focus on the difference between the bonding apparatus 37 of the present modification example and the bonding apparatus 37 of the above-described exemplary embodiment.

The bonding apparatus 37 may include a cutting device 64 instead of the adhesive force reducing device 58 shown in FIG. 6A, etc., as illustrated in FIG. 8A. The cutting device 64 is configured to cut the tape T along the edge of the chip C pressed onto the second substrate W2 by the pressing device 53. A cutting line is slightly larger than the edge of the chip C, and is set between the adjacent chips C. The cutting of the tape T may be performed using a laser beam or a cutter.

Thereafter, if the pressing device 53 releases the pressing of the chip C, the second substrate W2 with the tape T and the chip C attached thereto is obtained, as shown in FIG. 8B. Thereafter, the tape T is removed, and the second substrate W2 with the chip C attached thereto is obtained.

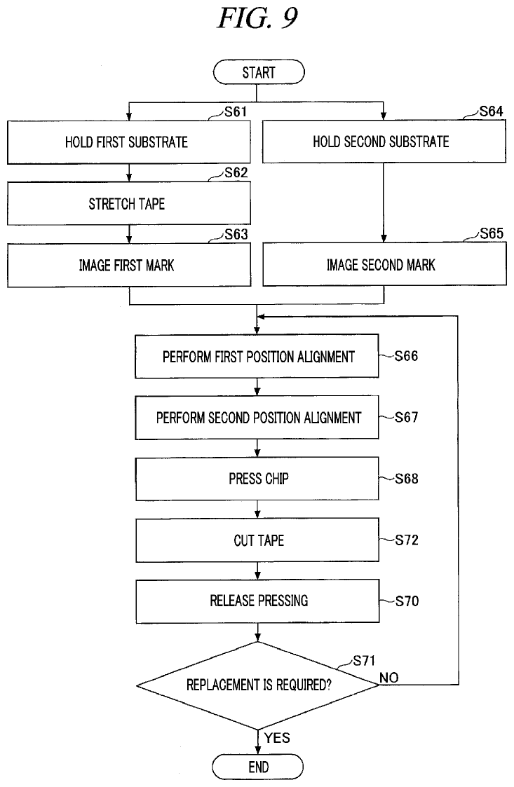

Now, referring to FIG. 9, an operation of the bonding apparatus 37 of the present modification example, that is, a bonding method will be described. Processes shown in FIG. 9 are performed under the control of the control device 9. The bonding method according to the present modification example includes cutting of the tape (S72) instead of the reduction of the adhesive force of the tape T shown in FIG. 7 (S69). The cutting of the tape T (S72) is performed by the cutting device 64.

So far, the exemplary embodiment of the bonding apparatus, the bonding system and the bonding method according to the present disclosure have been described. However, the present disclosure is not limited to the above-described exemplary embodiment or the like. Various changes, corrections, replacements, addition, deletion and combinations may be made within the scope of the claims, and all of these are included in the scope of the inventive concept of the present disclosure.

The present application claims priority to Japanese Patent Application No. 2019-153201, field on Aug. 23, 2019, which application is hereby incorporated by reference in their entirety.

### EXPLANATION OF CODES

32: Second transfer device (transfer mechanism)
37: Bonding apparatus
S1: First holder
S2: Second holder
S3: Pressing device
W1: First substrate
C: Chip
T: Tape
F: Ring frame
W2: Second substrate

1. A bonding apparatus, comprising:
a first holder configured to hold a first substrate divided into multiple chips with a tape and a ring frame therebetween, the first substrate being attached to the tape, and an edge of the tape being attached to the ring frame;
a second holder configured to hold a second substrate, which is disposed on an opposite side to the tape with respect to the first substrate therebetween, while maintaining a distance from the first substrate; and
a pressing device configured to press the multiple chips one by one with the tape therebetween to press and bond the corresponding chip to the second substrate.

2. The bonding apparatus of claim 1, further comprising:
an attracting device configured to attract an adjacent chip next to the corresponding chip pressed by the pressing device with the tape therebetween such that the adjacent chip does not come into contact with the second substrate.

3. The bonding apparatus of claim 2, further comprising:
a gas suction device configured to suck a gas of an attraction surface of the attracting device to attract the tape to the attraction surface of the attracting device; and
a gas supply configured to supply a gas to the attracting device and discharge the gas toward the tape from the attraction surface of the attracting device.

4. The bonding apparatus of claim 1, further comprising:
an expanding device configured to enlarge a gap between the multiple chips adjacent to each other by stretching the tape radially before the chips are pressed onto the second substrate by the pressing device.

5. The bonding apparatus of claim 1, further comprising:
an adhesive force reducing device configured to reduce an adhesive force of the tape at an interface between the tape and the corresponding chip pressed onto the second substrate by the pressing device.

6. The bonding apparatus of claim 1, further comprising:
a first imaging device configured to image a bonding surface of the first substrate and a first mark of the first substrate;
a second imaging device configured to image a bonding surface of the second substrate and a second mark of the second substrate; and
a first aligning device configured to perform alignment between the first substrate and the second substrate based on a position of the first mark and a position of the second mark.

7. The bonding apparatus of claim 6, further comprising:
a second aligning device configured to perform alignment between the corresponding chip of the first substrate and the pressing device based on the position of the first mark.

8. A bonding system, comprising:
a bonding apparatus as claimed in claim 1;
a modifying apparatus configured to modify a bonding surface of the first substrate or a bonding surface of the second substrate with plasma before the chips and the second substrate are bonded;
a hydrophilizing apparatus configured to hydrophilize the modified bonding surface of the first substrate or the modified bonding surface of the second substrate before the chips and the second substrate are bonded; and
a transfer device configured to transfer the first substrate or the second substrate to/from the modifying apparatus, the hydrophilizing apparatus, and the bonding apparatus.

9. A bonding method, comprising:
holding a first substrate, divided into multiple chips, by a first holder with a tape and a ring frame therebetween, the first substrate being attached to the tape, and an edge of the tape being attached to the ring frame;
holding a second substrate, which is disposed on an opposite side to the tape with respect to the first substrate therebetween, by a second holder while maintaining a distance from the first substrate; and
pressing the multiple chips one by one by a pressing device with the tape therebetween to press and bond the corresponding chip to the second substrate.

10. The bonding method of claim 9, further comprising:
attracting, by an attracting device, an adjacent chip next to the corresponding chip pressed by the pressing device with the tape therebetween such that the adjacent chip does not come into contact with the second substrate.

11. The bonding method of claim 10, further comprising:
sucking a gas of an attraction surface of the attracting device to attract the tape to the attraction surface of the attracting device; and
supplying a gas to the attracting device and discharging the gas toward the tape from the attraction surface of the attracting device.

12. The bonding method of claim 9, further comprising:
enlarging a gap between the multiple chips adjacent to each other by stretching the tape radially before pressing the chips onto the second substrate by the pressing device.

13. The bonding method of claim 9, further comprising:
reducing an adhesive force of the tape at an interface between the tape and the corresponding chip pressed onto the second substrate by the pressing device.

14. The bonding method of claim 9, further comprising:
imaging a bonding surface of the first substrate and a first mark of the first substrate;
imaging a bonding surface of the second substrate and a second mark of the second substrate; and
performing alignment between the first substrate and the second substrate based on a position of the first mark and a position of the second mark.

15. The bonding method of claim 14, further comprising:
performing alignment between the corresponding chip of the first substrate and the pressing device based on the position of the first mark.

16. The bonding method of claim 9, further comprising:
modifying a bonding surface of the first substrate or a bonding surface of the second substrate with plasma before bonding the chips and the second substrate; and
hydrophilizing the modified bonding surface of the first substrate or the modified bonding surface of the second substrate before bonding the chips and the second substrate.
